(19) United States
(12) Patent Application Publication
(10) Pub. No.: US 2025/0040320 A1
(43) Pub. Date: Jan. 30, 2025

(54) STRUCTURE OF LIGHT-EMITTING DEVICE AND PREPARATION METHOD THEREFOR

(71) Applicant: Enkris Semiconductor (Wuxi), Ltd., Wuxi (CN)

(72) Inventors: Liyang ZHANG, Wuxi (CN); Kai CHENG, Wuxi (CN)

(73) Assignee: Enkris Semiconductor (Wuxi), Ltd., Wuxi (CN)

(21) Appl. No.: 18/488,252

(22) Filed: Oct. 17, 2023

(30) Foreign Application Priority Data
Jul. 25, 2023 (CN) 202310925382.8

(51) Int. Cl. H01L 33/58; H01L 33/00; H01L 33/10; H01L 33/62

(52) U.S. Cl. CPC H01L 33/58; H01L 33/0093; H01L 33/10; H01L 33/62; H01L 2933/0058

(57) ABSTRACT

Disclosed are a light-emitting device structure and a preparation method therefor. The light-emitting device structure includes a buffer layer, where a material of the buffer layer is a transparent material; and a light-emitting structure disposed on a side of the buffer layer, where the light-emitting structure includes at least one light-emitting unit; where the buffer layer includes at least one microlens structure, the microlens structure includes at least two sub-layers, and each the light-emitting unit corresponds to at least one microlens structure. In the present disclosure, the buffer layer of the transparent material is utilized to manufacture the the microlens structure. On the one hand, a problem of total reflection is alleviated and light extraction efficiency of the light-emitting device is improved. On the other hand, no additional microlens structures is required, thereby reducing production cost.

### CROSS-REFERENCE TO RELATED APPLICATIONS

This application claims priority to Chinese Patent Application No. 202310925382.8, filed on Jul. 25, 2023, which is hereby incorporated by reference in its entirety.

### TECHNICAL FIELD

The present disclosure relates to the field of semiconductor technologies, and in particular, to a light-emitting device structure and a preparation method therefor.

### BACKGROUND

Light-Emitting Diodes (LED) are widely used in various fields due to their long lifespan, low energy consumption and other advantages. Especially with an increasing improvement of illumination performance, LEDs are commonly used as light-emitting devices in the lighting field. III-V group compound semiconductors represented by gallium nitride (GaN) have enormous application potential in the field of high brightness light-emitting diodes, lasers, and other optoelectronic devices due to their wide band gap, high electron saturation drift rate, and stable chemical properties, which have attracted widespread attention.

However, currently, semiconductor light-emitting diodes have a problem of low light-emitting efficiency.

### SUMMARY

In view of this, embodiments of the present disclosure provide a light-emitting device structure and a preparation method therefor to solve a problem that a microlens is easy to deform at a high temperature, thereby improving optical stability of a light-emitting device and improving light extraction efficiency of the light-emitting device.

According to an aspect of the present disclosure, a light-emitting device structure is provided by an embodiment of the present disclosure, including:
a buffer layer, where a material of the buffer layer is a transparent material; and
a light-emitting structure disposed on a side of the buffer layer, where the light-emitting structure includes at least one light-emitting unit; where
the buffer layer includes at least one microlens structure, the microlens structure includes at least two sub-layers, and each the light-emitting unit corresponds to at least one microlens structure.

As an optional embodiment, the light-emitting structure is disposed on a focal plane of the microlens structure.

As an optional embodiment, the microlens structure includes a plurality of sub-layers with different refractive indices.

As an optional embodiment, the different refractive indices of the plurality of sub-layers of the microlens structure gradually decrease or increase first and then decrease in a direction from the light-emitting structure to the microlens structure, and a change mode of the different refractive indices of the plurality of sub-layers of the microlens structure includes any one of a uniform change, a jump change, and a step-like change.

As an optional embodiment, the microlens structure includes a plurality of AlGaN sub-layers with different content of Al, the different content of Al gradually decreases or increases first and then decreases in a direction from the light-emitting structure to the microlens structure, and a change mode of the content of Al content includes any one of a uniform change, a jump change, and a step-like change.

As an optional embodiment, a size of the light-emitting unit is the same as each other, each the light-emitting unit corresponds to one microlens structure, and a size of at least one microlens structure is different from sizes of other microlens structures.

As an optional embodiment, curvature of the microlens structure is the same as each other, and a thickness of at least one microlens structure is different from thicknesses of other microlens structures.

As an optional embodiment, a thickness of the microlens structure is the same as each other, and curvature of at least one microlens structure is different from curvature of other microlens structures.

As an optional embodiment, the number of microlens structures corresponding to at least one light-emitting unit is different from number of microlens structures corresponding to other light-emitting units.

As an optional embodiment, the microlens structure includes at least one of a spherical convex lens, an aspheric convex lens, a spherical concave lens, and an aspheric concave lens.

As an optional embodiment, a material of the buffer layer includes at least one of AlN, GaN, AlGaN, and AlInGaN.

As an optional embodiment, the light-emitting device structure further includes:
a substrate structure disposed on a side, away from the light-emitting structure, of the buffer layer, where the substrate structure includes at least one opening penetrating through the substrate structure, and each the light-emitting unit corresponds to an opening.

As an optional embodiment, the light-emitting device structure further includes:
an AlN film disposed on a surface, away from the light-emitting structure, of the microlens structure.

As an optional embodiment, the light-emitting device structure further includes:
a metal lens with a medium hole, disposed on a surface, away from the light-emitting structure, of the microlens structure.

As an optional embodiment, the microlens structure further includes:
a first Distributed Bragg Reflector (DBR)_layer disposed on a side, close to the light-emitting structure, of the microlens structure.

As an optional embodiment, the light-emitting device structure further includes:
a second Distributed Bragg Reflector (DBR) layer disposed on a side, away from the microlens structure, of the light-emitting structure.

According to another aspect of the present disclosure, a preparation method for a light-emitting device structure is provided by an embodiment of the present disclosure, and the preparation method includes: providing a substrate; growing a buffer layer on the substrate, where a material of the buffer layer is a transparent material; growing a light-emitting structure on the buffer layer, where the light-emitting structure includes at least one light-emitting unit; and etching the substrate from a side away from the buffer layer to remove the substrate, and etching a surface, away from the light-emitting structure, of the buffer layer to form at least one microlens structure, where the microlens structure includes at least two sub-layers, and each the light-emitting unit corresponds to at least one microlens structure.

As an optional embodiment, the etching in the step of etching the substrate from a side away from the buffer layer to remove the substrate, the etching is a patterned etching, and the substrate remained becomes a substrate structure, serving as a barrier between adjacent two light-emitting units.

As an optional embodiment, a size of light-emitting unit is the same as each other, each the light-emitting unit corresponds to a microlens structure, and a size of at least one microlens structure is different from sizes of other microlens structures.

As an optional embodiment, at least one light-emitting unit corresponds to a different quantity of the microlens structure from other light-emitting units.

### BRIEF DESCRIPTION OF THE DRAWINGS

FIG. 1 is a schematic structural diagram of a light-emitting device structure according to an embodiment of the present disclosure.

FIG. 2a to FIG. 2d are variation trends of refractive indices of a plurality of sub-layers of a microlens structure of a light-emitting device according to an embodiment of the present disclosure.

FIG. 3 is a schematic structural diagram of a light-emitting device structure according to another embodiment of the present disclosure.

FIG. 4 is a schematic structural diagram of a light-emitting device structure according to still another embodiment of the present disclosure.

FIG. 5 is a schematic structural diagram of a light-emitting device structure according to yet still another embodiment of the present disclosure.

FIG. 6 is a schematic structural diagram of a light-emitting device structure according to yet still another embodiment of the present disclosure.

FIG. 7 is a schematic structural diagram of a light-emitting device structure according to yet still another embodiment of the present disclosure.

FIG. 8 is a schematic structural diagram of a light-emitting device structure according to yet still another embodiment of the present disclosure.

FIG. 9 is a schematic structural diagram of a light-emitting device structure according to yet still another embodiment of the present disclosure.

FIG. 10 is a flowchart of a preparation method for a light-emitting device structure according to an embodiment of the present disclosure.

FIG. 11 to FIG. 15 are decomposition diagrams of a light-emitting device structure during a preparation process according to an embodiment of the present disclosure.

FIG. 16 is a schematic structural diagram of a light-emitting device structure according to yet still another embodiment of the present disclosure.

### DETAILED DESCRIPTION OF THE EMBODIMENTS

Technical solutions in embodiments of the present disclosure will be clearly and completely described with reference to accompanying drawings corresponding to the embodiments of the present disclosure in the following description. Apparently, the described embodiments are only some, not all, embodiments of the present disclosure. Based on the embodiments in the present disclosure, all other embodiments obtained by those skilled in the art without creative efforts shall fall within the protection scope of the present disclosure.

For ordinary unpackaged light-emitting diodes, their light-emitting efficiency is generally only a few percent, and a large amount of energy accumulates inside the device and cannot emit, which not only causes energy waste but also affects the lifespan of the device. Therefore, it is crucial to improve light extraction efficiency of the semiconductor light-emitting diode.

Based on application requirements mentioned above, many methods to improve the light extraction efficiency of light-emitting diodes have been applied to structures of the device. For example, a microlens structure may be manufactured on a surface of LED. However, the microlens is commonly made of an organic resin material, which makes the microlens easy to be deformed at a high temperature, thereby reducing stability of optical performance of LED.

To solve a technical problem that a microlens is prone to deform at a high temperature, a light-emitting device structure and a preparation method therefor are provided by the present disclosure. The light-emitting device structure includes a buffer layer, where a material of the buffer layer is a transparent material; and a light-emitting structure disposed on a side of the buffer layer, where the light-emitting structure includes at least one light-emitting unit; where the buffer layer includes at least one microlens structure, the microlens structure includes at least two sub-layers, and each the light-emitting unit corresponds to at least one microlens structure. The present disclosure utilizes the buffer layer, which is made of the transparent material, to prepare the microlens structure. On the one hand, a problem of total reflection may be alleviated so that light extraction efficiency of the light-emitting device may be improved. On the other hand, no additional microlens structures need to be prepared, thereby reducing production cost.

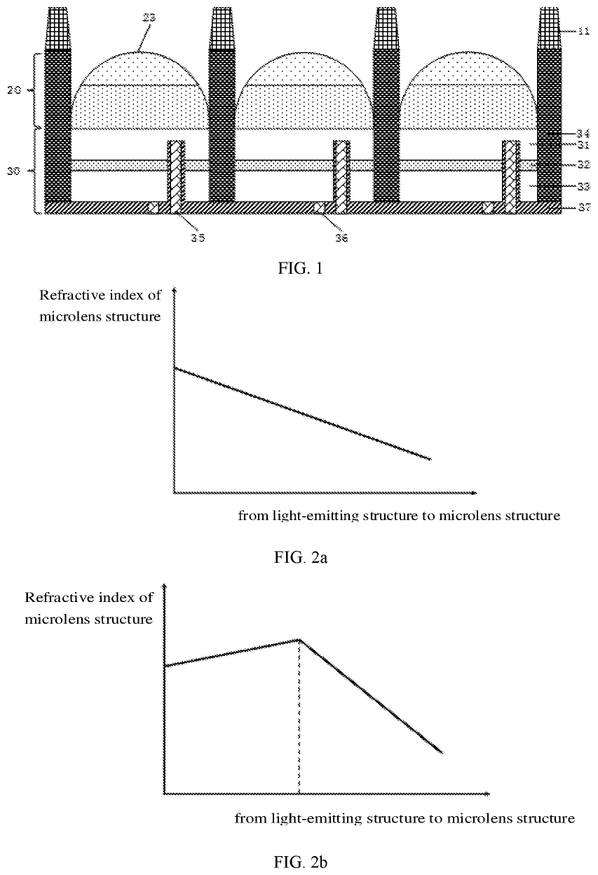

The light-emitting device structure and the preparation method therefor mentioned in the present disclosure will be further illustrated with reference to FIG. 1 to FIG. 16.

FIG. 1 is a schematic structural diagram of a light-emitting device structure according to an embodiment of the present disclosure. As shown in FIG. 1, the light-emitting device structure includes a buffer layer 20, where a material of the buffer layer 20 is a transparent material; and a light-emitting structure 30 disposed on a side of the buffer layer 20, where the light-emitting structure 30 includes at least one light-emitting unit; where the buffer layer 20 includes at least one microlens structure 23, the microlens structure 23 includes at least two sub-layers, and each the light-emitting unit corresponds to the at least one microlens structure 23.

In the present embodiment, the microlens structure 23 includes at least one of a spherical convex lens, an aspheric convex lens, a spherical concave lens, and an aspheric concave lens. The light-emitting structure 30 is disposed on a focal plane of the microlens structure 23, so that transmitted light may be refracted parallel to each other and parallel to a central axis of the lens, and collimation may be maximized, thereby maximizing capture efficiency.

In the present embodiment, the material of the buffer layer 20 includes at least one of AlN, GaN, AlGaN, and AlInGaN. The microlens structure 23 is manufactured based on the buffer layer 20, therefore a material of the microlens structure 23 also includes at least one of AlN, GaN, AlGaN, and AlInGaN. The microlens structure 23 is not easy to deform at a high temperature, thereby improving optical stability of the light-emitting device.

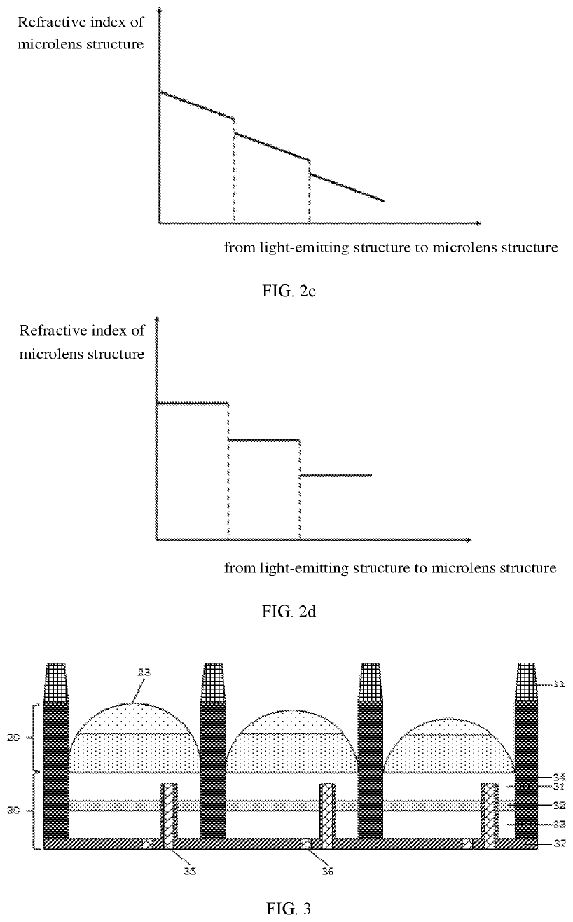

In an embodiment, FIG. 2a to FIG. 2d are variation trends of refractive indices of a plurality of sub-layers of a microlens structure of a light-emitting device according to an embodiment of the present disclosure. The microlens structure 23 includes a plurality of sub-layers with different refractive indices, and the different refractive indices of the plurality of sub-layers of the microlens structure 23 gradually decrease (as shown in FIG. 2a) or increase first and then decrease (as shown in FIG. 2b) in a direction from a light-emitting structure 30 to the microlens structure 23. A change mode of the different refractive indices of the plurality of sub-layers of the microlens structure 23 includes any one of a uniform change (as shown in FIG. 2a), a jumping change (as shown in FIG. 2c), and a step-like change (as shown in FIG. 2d). A main reason for low light extraction efficiency is that there is a large difference in refractive index between the light-emitting structure and air. As the microlens structure 23 is designed to include the plurality of sub-layers with different refractive indices, a refractive index difference of a contact interface between the light-emitting structure 30 and the microlens structure 23 and a refractive index difference of a contact interface between the microlens structure 23 and air are both reduced, so that possibility of a total reflection of light may be reduced, thereby improving utilization rate of light and the light extraction efficiency of the light-emitting device.

In an embodiment, the microlens structure 23 includes a plurality of AlGaN sub-layers with different Al content, the different Al content of the plurality of AlGaN sub-layers gradually decrease or increase first and then decrease in a direction from the light-emitting structure 30 to the microlens structure 23, and a change mode of the Al content includes any one of a uniform change, a jumping change, and a step-like change. A variation trend of Al content in the AlGaN material is the same as that of a refractive index of the AlGaN material. Therefore, by increase the Al content, the refractive index of the AlGaN material may be improved.

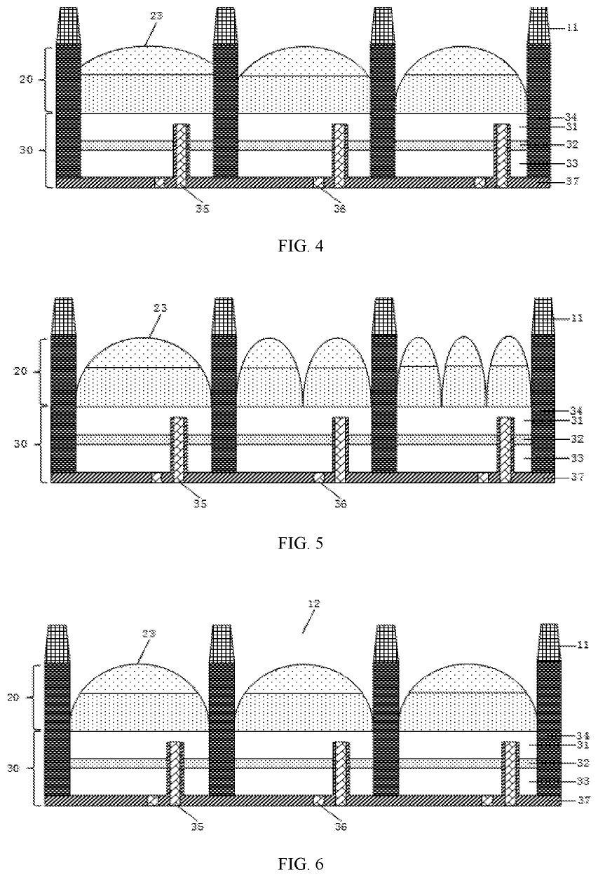

In an embodiment, a size of a light-emitting unit is the same as each other, each the light-emitting unit corresponds to a microlens structure 23, and a size of at least one microlens structure 23 is different from sizes of other microlens structures 23. FIG. 3 is a schematic structural diagram of a light-emitting device structure according to another embodiment of the present disclosure. As shown in FIG. 3, curvature of the microlens structure 23 is the same as each other, and a thickness of at least one microlens structure 23 is different from thicknesses of other microlens structures 23. Specifically, when colors of light emitted by each light-emitting unit of the light-emitting structure 30 include red, green, and blue, frequency of the red light is lower than others and a refractive index of the red light in the medium is smaller than others. As the higher the refractive index is, the shorter the focal length is, a focal length of the red light is the longest. To ensure that the light-emitting units of the red, green, and blue light are all on the focal plane of the microlens structure 23, a thickness of the microlens structure 23 corresponding to red light may be designed to be the maximum, a thickness of the microlens structure 23 corresponding to green light may be designed to be in the middle, and a thickness of the microlens structure 23 corresponding to blue light may be designed to be the minimum. FIG. 4 is a schematic structural diagram of a light-emitting device structure according to still another embodiment of the present disclosure. As shown in FIG. 4, a thickness of the microlens structure 23 is the same as each other, and curvature of at least one microlens structure 23 is different from curvature of other microlens structures 23. Specifically, when colors of light emitted by each light-emitting unit of the light-emitting structure 30 include red, green, and blue, the focal length of the red light is the longest. As the larger the curvature radius is, the larger the focal length, the focal length of the red light may be reduced by reducing the curvature radius of the microlens structure 23 corresponding to the red light. To ensure that the light-emitting units of the red, green, and blue light are all on the focal plane of the microlens structure 23, the curvature radius of the microlens structure 23 corresponding to the red light may be designed to be the minimum, the curvature radius of the microlens structure 23 corresponding to the green light may be designed to be in the middle, and the curvature radius of the microlens structure 23 corresponding to the blue light may be designed to be the maximum.

In an embodiment, FIG. 5 is a schematic structural diagram of a light-emitting device structure according to yet still another embodiment of the present disclosure. As shown in FIG. 5, the number of the microlens structure 23 corresponding to at least one light-emitting unit is different from number of the microlens structure 23 corresponding to other light-emitting units. Sizes of the light-emitting units may be the same or different. A size of the microlens structure 23 may be changed by designing different quantity of microlens structures 23 corresponding to one light-emitting unit.

In an embodiment, FIG. 6 is a schematic structural diagram of a light-emitting device structure according to yet still another embodiment of the present disclosure. As shown in FIG. 6, the light-emitting device structure further includes a substrate structure 11 disposed on a side, away from the light-emitting structure 30, of the buffer layer 20, where the substrate structure 11 includes at least one opening 12 penetrating through the substrate structure 11, and each the light-emitting unit corresponds to an opening 12. A material of the substrate structure 11 includes silicon, so that it can serve as a barrier between adjacent light-emitting units to avoid light crosstalk.

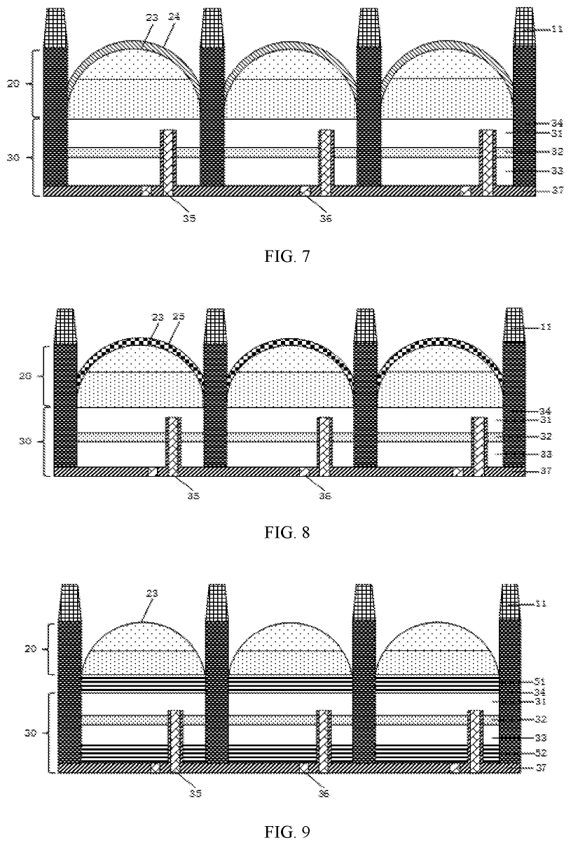

In an embodiment, FIG. 7 is a schematic structural diagram of a light-emitting device structure according to yet still another embodiment of the present disclosure. As shown in FIG. 7, the light-emitting device structure further includes an AlN film 24 disposed on a surface, away from the light-emitting structure 30, of the microlens structure 23. The AlN film 24 plays a role of an antireflective film, and a preparation method therefor includes metal organic chemical vapor deposition or physical vapor deposition. With arrangement of the AlN film 24, light reflection may be further reduced to improve a transmittance rate, thereby improving light extraction efficiency.

In an embodiment, FIG. 8 is a schematic structural diagram of a light-emitting device structure according to yet still another embodiment of the present disclosure. As shown in FIG. 8, the light-emitting device structure further includes a metal lens 25 with a medium hole, where the metal lens 25 is disposed on a surface, away from the light-emitting structure 30, of the microlens structure 23. The medium hole is filled with a medium material of a high refractive index and an antireflective film material, and a shape of the medium hole may include at least one of a circle, a triangle, a rectangle, and a hexagon, which is not specifically limited in the present disclosure. With arrangement of the metal lens 25 with a medium hole, a light output direction may be adjusted and the light extraction efficiency may be improved.

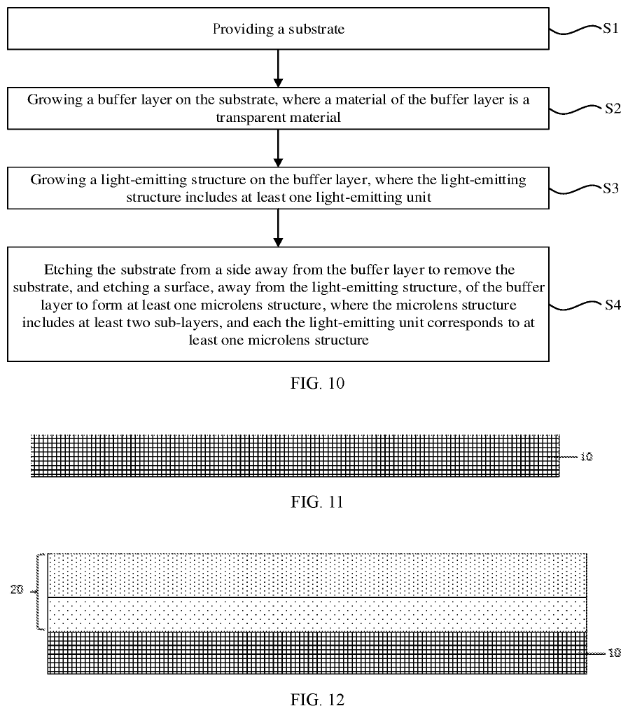

In an embodiment, FIG. 9 is a schematic structural diagram of a light-emitting device structure according to yet still another embodiment of the present disclosure. As shown in FIG. 9, the microlens structure further includes a first DBR layer 51 disposed on a side, close to the light-emitting structure 30, of the microlens structure 23. The first DBR layer 51 is also manufactured based on the buffer layer 20 with a plurality of sub-layers, so that the DBR structure and the microlens structure through the buffer layer 20 may be manufactured simultaneously to simplify a preparation process and reduce cost. The light-emitting device structure further includes a second DBR layer 52 disposed on a side, away from the microlens structure 23, of the light-emitting structure 30. Reflectivity of the second DBR layer 52 is greater than that of the first DBR layer 51. The light emitted by the light-emitting structure 30 may pass through the first DBR layer 51 and emit from the surface, away from the light-emitting structure 30, of the microlens structure 23. A material of the first DBR layer 51 may be an III-V semiconductor material. The second DBR layer 52 may be a Bragg reflector, and a material of the second DBR layer 52 may be a set of multi-cycle materials selected from material groups including TiO₂/SiO₂, Ti₃O₅/SiO₂, Ta₂O₅/SiO₂, Ti₃O₅/Al₂O₃, ZrO₂/SiO₂, and TiO₂/Al₂O₃, which is not limited in the embodiment of the present disclosure.

According to another aspect of the present disclosure, FIG. 10 is a flowchart of a preparation method for a light-emitting device structure according to an embodiment of the present disclosure, and FIG. 11 to FIG. 15 are decomposition diagrams of a light-emitting device structure during a preparation process according to an embodiment of the present disclosure. As shown in FIG. 10, the preparation method for the light-emitting device structure is provided by an embodiment of the present disclosure, including the following steps.

As shown in FIG. 11, Step S1: providing a substrate. A material of the substrate 10 includes silicon.

As shown in FIG. 12, Step S2: growing a buffer layer on the substrate, where a material of the buffer layer is a transparent material. The material of the buffer layer 20 includes at least one of AlN, GaN, AlGaN, and AlInGaN.

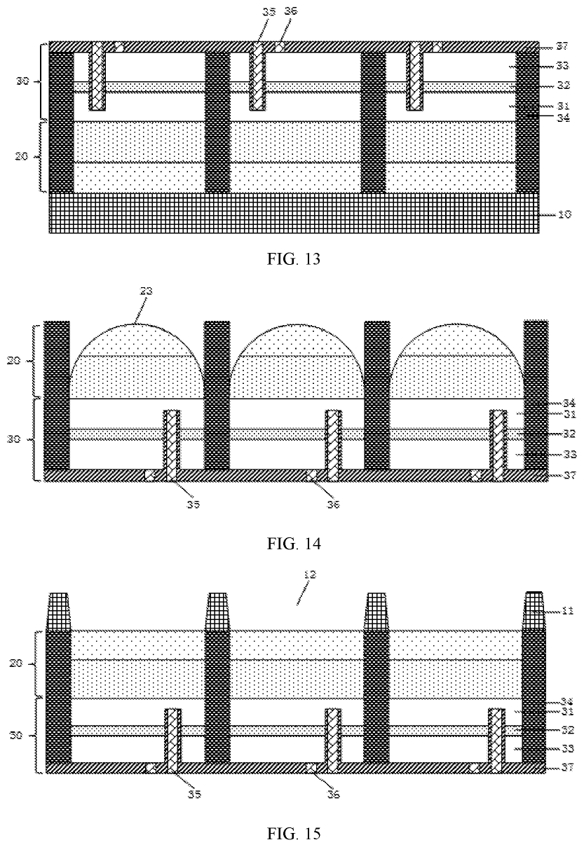

As shown in FIG. 13, Step S3: growing a light-emitting structure on the buffer layer, where the light-emitting structure includes at least one light-emitting unit. The light-emitting structure 30 includes: a first semiconductor layer 31, an active layer 32, a second semiconductor layer 33, an insulation structure 34, at least a set of a first electrode 35 and a second electrode 36; where the first electrode 35 is connected to the first semiconductor layer 31, the second electrode 36 is connected to the second semiconductor layer 33, the first electrode 35 and the second electrode 36 are blocked by an insulation material 37, and adjacent two light-emitting units are blocked by the insulation structure 34.

As shown in FIG. 14, Step S4: etching the substrate from a side away from the buffer layer to remove the substrate, and etching a surface, away from the light-emitting structure, of the buffer layer to form at least one microlens structure, where the microlens structure includes at least two sub-layers, and each the light-emitting unit corresponds to at least one microlens structure.

In an embodiment, as shown in FIG. 15, the etching performed on the substrate 10 in Step S4 is patterned etching, and the substrate 10 remained becomes a substrate structure 11, serving as a barrier between adjacent two light-emitting units. The substrate structure 11 is disposed on a side, away from the light-emitting structure 30, of the buffer layer 20, where the substrate structure 11 includes at least one opening 12 penetrating through the substrate structure 11, and each the light-emitting unit corresponds to an opening 12. The surface of the buffer layer 20 exposed by the opening 12 may be etched to form a microlens structure 23. A material of the substrate structure 11 includes silicon, so that it may serve as a barrier between adjacent two light-emitting units to avoid light crosstalk.

In an embodiment, a size of a light-emitting unit is the same as each other, each the light-emitting unit corresponds to a microlens structure 23, and a size of at least one microlens structure 23 is different from sizes of other microlens structures 23. As shown in FIG. 3, curvature of the microlens structure 23 is the same as each other, and a thickness of at least one microlens structure 23 is different from thicknesses of other microlens structures 23; or as shown in FIG. 4, a thickness of the microlens structure 23 is the same as each other, and curvature of at least one microlens structure 23 is different from curvature of other microlens structures 23. By etching, the sizes of the microlens structures 23 corresponding to the light-emitting units of red, green, and blue light respectively may be changed, so that the light-emitting units of red, green, and blue light may all be disposed on the focal plane of the microlens structures 23, the transmitted light of different colors may be refracted parallel to each other and parallel to a central axis of the lens, thereby maximizing collimation and maximizing the capture efficiency.

In an embodiment, the number of the microlens structures 23 corresponding to at least one light-emitting unit is different from number of the microlens structures 23 corresponding to other light-emitting units by etching. And sizes of the light-emitting units may be the same or different. By etching a different quantity of the microlens structures 23 in the buffer layer 20 corresponding to a light-emitting unit, a size of the microlens structure 23 may be changed.

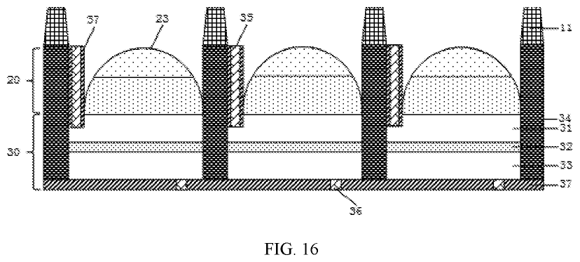

In an embodiment, FIG. 16 is a schematic structural diagram of a light-emitting device structure according to an embodiment of the present disclosure. A groove is formed on a side, away from the microlens structure 23, of the light-emitting structure 30, which completely penetrates through a second semiconductor layer 33 and an active layer 32, and partially penetrates a first semiconductor layer 31. A first electrode 35 is prepared in the groove, and the first electrode 35, the second semiconductor layer 33, the active layer 32 are insulated and blocked with each other by an insulation material 37, and the first electrode 35 is connected to the first semiconductor layer 31. A second electrode 36 is manufactured on a side, away from the active layer 32, of the second semiconductor layer 33. The second electrode 36 is insulated and blocked from the first electrode 35, thereby forming the light-emitting device structure as shown in FIG. 1. It is also possible to form a groove on a side, close to the microlens structure 23, of the light-emitting structure 30, which completely penetrates through the buffer layer 20 and partially penetrates the first semiconductor layer 31. The first electrode 35 is prepared in the groove, and the first electrode 35 is insulated and blocked from the buffer layer 20 by the insulation material 37. The second electrode 36 is manufactured on a side, away from the active layer 32, of the second semiconductor layer 33, thereby forming the light-emitting device structure as shown in FIG. 16.

A structure of a light-emitting device and a preparation method therefor is provided by the present disclosure, and the light-emitting device structure includes a buffer layer, where a material of the buffer layer is a transparent material; and a light-emitting structure disposed on a side of the buffer layer, where the light-emitting structure includes at least one light-emitting unit; where the buffer layer includes at least one microlens structure, the microlens structure includes at least two sub-layers, and each the light-emitting unit corresponds to at least one microlens structure.

According to the light-emitting device structure and the preparation method therefor provided by the present disclosure, a microlens structure is designed to make sure that an incident angle of light emitted by the light-emitting structure and output from a surface of the microlens structure is always less than a critical angle of total reflection, so that total reflection may not occur, and most of the light may be transmitted from the surface of the microlens structure, thereby improving light extraction efficiency of the light-emitting device.

According to the light-emitting device structure and the preparation method therefor provided by the present disclosure, a microlens structure is manufactured based on a buffer layer, so that there is no need to manufacture an additional microlens structure, thereby effectively reducing a thickness of the device, improving a transmittance rate and reducing production cost. Meanwhile, the microlens structure prepared by the buffer layer is not easy to deform at a high temperature, thereby improving optical stability of the light-emitting device.

According to the light-emitting device structure and the preparation method therefor provided by the present disclosure, a multi-layer buffer layer is utilized to design the microlens structure. The microlens structure includes a plurality of sub-layers with different refractive indices, so that a difference in refractive index between a contact interface between the light-emitting structure and the microlens structure and a contact interface between the microlens structure and air may be reduced, thereby further reducing possibility of total reflection of light, improving a utilization rate of light, and improving the light extraction efficiency of the light-emitting device.

According to the light-emitting device structure and the preparation method therefor provided by the present disclosure, microlens structures with different sizes are designed to correspond to red, green, and blue light, so that uniformity of the light output may be improved while improving the light extraction efficiency of the three-color light.

It should be understood that the term “including” and its variations used in the present disclosure are open-ended, that is, “including but not limited to”. The term “one embodiment” means “at least one embodiment”, the term “another embodiment” means “at least one other embodiment”. In this specification, the schematic expressions of the above terms do not necessarily refer to the same embodiments or examples. Moreover, the specific features, structures, materials, or characteristics described can be combined in an appropriate manner in any one or more embodiments or examples. In addition, those of skill in the art may combine and permutation the different embodiments or examples described in this specification, as well as the features of different embodiments or examples, without contradiction.

The above embodiments are only the preferred embodiments of the present disclosure, and are not intended to limit the protection scope of the present disclosure. Any modification, equivalent replacement, improvement and so on made in the spirit and principle of the present disclosure shall fall into the protection scope of the present disclosure.

What is claimed is:

1. A light-emitting device structure, comprising:
a buffer layer, wherein a material of the buffer layer is a transparent material; and
a light-emitting structure disposed on a side of the buffer layer, wherein the light-emitting structure comprises at least one light-emitting unit; wherein
the buffer layer comprises at least one microlens structure, the microlens structure comprises at least two sub-layers, and each the light-emitting unit corresponds to at least one microlens structure.

2. The light-emitting device structure according to claim 1, wherein the light-emitting structure is disposed on a focal plane of the microlens structure.

3. The light-emitting device structure according to claim 1, wherein the microlens structure comprises a plurality of sub-layers with different refractive indices.

4. The light-emitting device structure according to claim 3, wherein the different refractive indices of the plurality of sub-layers of the microlens structure gradually decrease or increase first and then decrease in a direction from the light-emitting structure to the microlens structure, and a change mode of the different refractive indices of the plurality of sub-layers of the microlens structure comprises any one of a uniform change, a jump change, and a step-like change.

5. The light-emitting device structure according to claim 3, wherein the microlens structure comprises a plurality of AlGaN sub-layers with different content of Al, the different content of Al gradually decreases or increases first and then decreases in a direction from the light-emitting structure to the microlens structure, and a change mode of the content of Al content comprises any one of a uniform change, a jump change, and a step-like change.

6. The light-emitting device structure according to claim 1, wherein a size of the light-emitting unit is the same as each other, each the light-emitting unit corresponds to one microlens structure, and a size of at least one microlens structure is different from sizes of other microlens structures.

7. The light-emitting device structure according to claim 6, wherein curvature of the microlens structure is the same as each other, and a thickness of at least one microlens structure is different from thicknesses of other microlens structures.

8. The light-emitting device structure according to claim 6, wherein a thickness of the microlens structure is the same as each other, and curvature of at least one microlens structure is different from curvature of other microlens structures.

9. The light-emitting device structure according to claim 1, wherein the number of microlens structures corresponding to at least one light-emitting unit is different from number of microlens structures corresponding to other light-emitting units.

10. The light-emitting device structure according to claim 1, wherein the microlens structure comprises at least one of a spherical convex lens, an aspheric convex lens, a spherical concave lens, and an aspheric concave lens.

11. The light-emitting device structure according to claim 1, wherein a material of the buffer layer comprises at least one of AlN, GaN, AlGaN, and AlInGaN.

12. The light-emitting device structure according to claim 1, further comprising:
a substrate structure disposed on a side, away from the light-emitting structure, of the buffer layer, wherein the substrate structure comprises at least one opening penetrating through the substrate structure, and each the light-emitting unit corresponds to an opening.

13. The light-emitting device structure according to claim 1, further comprising:
an AlN film disposed on a surface, away from the light-emitting structure, of the microlens structure.

14. The light-emitting device structure according to claim 1, further comprising:
a metal lens with a medium hole, disposed on a surface, away from the light-emitting structure, of the microlens structure.

15. The light-emitting device structure according to claim 1, wherein the microlens structure further comprises:
a first Distributed Bragg Reflector (DBR) layer disposed on a side, close to the light-emitting structure, of the microlens structure.

16. The light-emitting device structure according to claim 1, further comprising:
a second Distributed Bragg Reflector (DBR) layer disposed on a side, away from the microlens structure, of the light-emitting structure.

17. A preparation method for a light-emitting device structure, comprising:
providing a substrate;
growing a buffer layer on the substrate, wherein a material of the buffer layer is a transparent material;
growing a light-emitting structure on the buffer layer, wherein the light-emitting structure comprises at least one light-emitting unit; and
etching the substrate from a side away from the buffer layer to remove the substrate, and etching a surface, away from the light-emitting structure, of the buffer layer to form at least one microlens structure, wherein the microlens structure comprises at least two sub-layers, and each the light-emitting unit corresponds to at least one microlens structure.

18. The preparation method according to claim 17, wherein in the step of etching the substrate from a side away from the buffer layer to remove the substrate, the etching is a patterned etching, and the substrate remained becomes a substrate structure, serving as a barrier between adjacent two light-emitting units.

19. The preparation method according to claim 17, wherein a size of light-emitting unit is the same as each other, each the light-emitting unit corresponds to a microlens structure, and a size of at least one microlens structure is different from sizes of other microlens structures.

20. The preparation method according to claim 17, wherein at least one light-emitting unit corresponds to a different quantity of the microlens structure from other light-emitting units.
